(19) United States
(12) Patent Application Publication
(10) Pub. No.: US 2009/0278152 A1
(43) Pub. Date: Nov. 12, 2009

(54) LIGHT EMITTING DIODE AND PACKAGE METHOD THEREOF

(75) Inventors: CHIA CHEN CHANG, YILAN COUNTY (TW); YI HSUN CHEN, TAIPEI CITY (TW); CHI WEI LIAO, TAIPEI CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/435,937

(22) Filed: May 5, 2009

(30) Foreign Application Priority Data
May 8, 2008 (CN) 200810097277.5

(51) Int. Cl. H01L 33/00; H01L 21/02

(52) U.S. Cl. 257/98; 438/26; 257/E33.055; 257/E21.002

(57) ABSTRACT

A light emitting diode comprises a sheet-like package body, a barricade, a light emitting diode die, and fluorescent filler. The sheet-like package body has a die-bonding region. The barricade is a transparent wall that is disposed on the die-bonding region, and is integrated with the sheet-like package body or is adhered to sheet-like package body. The light emitting diode die is disposed on the region enclosed by the barricade, and the fluorescent filler is also filled into the region and surrounds the light emitting diode die. The light emitting diode and the method for packaging the light emitting diode can improve the uniformity and efficiency of the outputting light emitted from the light emitting diode, and the loss of the outputted light is reduced.

### BACKGROUND OF THE INVENTION

1. Field of the Invention

The present invention relates to a light emitting diode and a package method thereof, and relates more particularly to a light emitting diode and a package method for improving the coating technology of fluorescent powder to increase the uniformity of output light.

2. Description of the Related Art

The current white light emitting diode is manufactured by coating fluorescent powder or fluorescent paste on a light emitting diode die and encapsulating the LED die.

As shown in FIG. 1, U.S. Pat. No. 6,879,490 discloses a light emitting diode 8 which comprises a sheet-like package body 80 and a light emitting diode die 81. The sheet-like package body 80 comprises a cavity 82. The light emitting diode 81 is disposed in the cavity 82. The side walls 820 of the cavity 82 extend diagonally so as to reflect the light emitted by the light emitting diode die 81. Fluorescent paste 83 is filled in the cavity 82. The uniformity and efficiency of the output light is improved by the reflection of the inclined side walls 820.

However, the light emitting diode 8 is merely superior to the conventional light emitting diode having a cavity with vertical side walls. In fact, the inclined side walls of the cavity somewhat shield the light emitted from the light emitting diode die. Therefore, the problems of light loss and uneven light output should be further resolved.

### SUMMARY OF THE INVENTION

The present invention provides a light emitting diode and a package method thereof, utilizing an inexpensive method to improve the efficiency and uniformity of light output.

In view of aforesaid aspects, the present invention provides a light emitting diode which comprises a sheet-like package body, a barricade, a light emitting diode die and fluorescent filler. The sheet-like package body has a die-bonding region, and the barricade is a transparent enclosure also disposed on the die-bonding region. The light emitting diode die is enclosed by the barricade. The fluorescent filler is filled in the region enclosed by the barricade, and covers the surroundings of the light emitting diode die.

The present invention provides a package method of a light emitting diode, comprising the steps of: performing a die bonding step to mount a light emitting diode die on a sheet-like package body; performing a transparent barricade disposition step to dispose a transparent barricade on the sheet-like package body to enclose the light emitting diode die; and performing a fluorescent filler filling step to overlay the region enclosed by the barricade with fluorescent filler.

In another embodiment, the transparent barricade disposition step can be performed prior to the die bonding step. That is, the transparent barricade is disposed during the manufacturing step of the sheet-like package body.

According to the light emitting diode and the package method of the present invention, the barricade is integrated into the sheet-like package body or is attached to the sheet-like package body. The region enclosed by the barricade is circular, square or rectangular. The materials of the barricade and an encapsulation body outside the light emitting diode such as silicone and transparent epoxy have the same or approximate refraction coefficient. The fluorescent filler is fluorescent powder or fluorescent paste. The sheet-like package body is flat or concave.

Compared with the prior arts, the light emitting diode and the package method of the present invention can have a uniform thickness of the fluorescent filler. Each of the light beams emitted from the light emitting diode die has a substantially identical light path through the fluorescent filler so that excellent uniformity of light output is achieved. Furthermore, the barricade allows the light to pass through it rather than being reflected, and hence the light efficiency of the light emitting diode die is not negatively affected by shielding and consequent light loss.

### BRIEF DESCRIPTION OF THE DRAWINGS

The invention will be described according to the appended drawings in which:

FIG. 1 illustrates a cross-sectional diagram of a current light emitting diode;

FIG. 2 is a perspective diagram of a light emitting diode in accordance with an embodiment of the present invention; and

FIG. 3 is a cross-sectional diagram taken along the line A-A in FIG. 2.

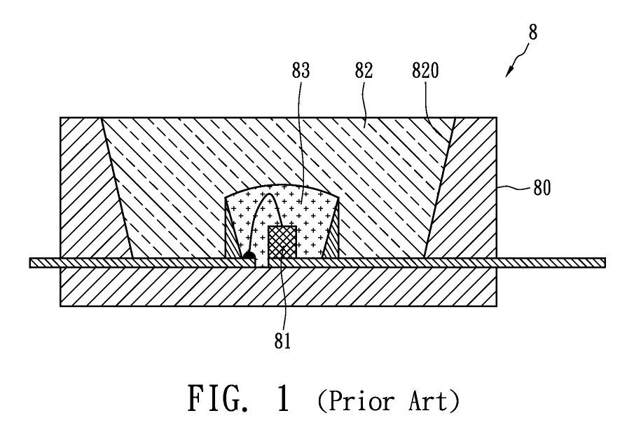

### DETAILED DESCRIPTION OF THE INVENTION

To provide a better understanding of the features of the present invention, the following descriptions further explain the features in view of several embodiments.

According to the light emitting diode and the package method of the present invention, a transparent barricade is integrated with the die-bonding region of a sheet-like package body or is attached to the sheet-like package body. The material of the barricade is silicone, transparent epoxy or other transparent material. The refraction coefficient of the barricade is approximately equal to that of an encapsulation body outside the light emitting diode. The fluorescent powder or fluorescent paste is overlaid on the region enclosed by the barricade during filling. The fluorescent powder or fluorescent paste can be evenly formed on the surroundings of the light emitting diode die so as to achieve the objective of high uniformity of light output.

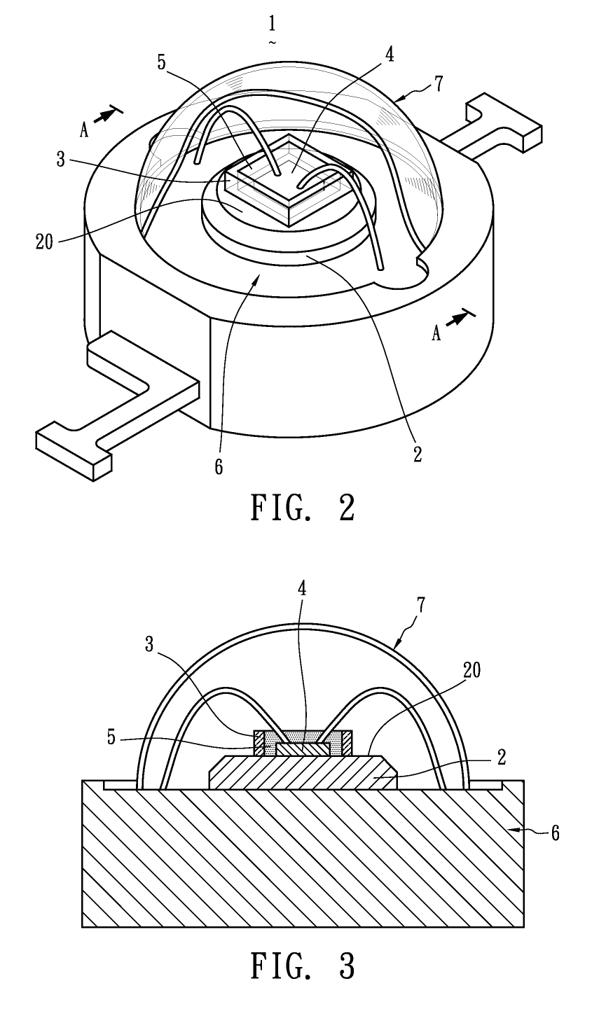

As shown in FIGS. 2 and 3, the light emitting diode 1 according to one embodiment of the present invention comprises a sheet-like package body 2, a barricade 3, a light emitting diode die 4, fluorescent filler 5, a substrate 6 and a cover 7. The sheet-like package body 2 is mounted on the substrate 6, and has a die-bonding region 20 on which the light emitting diode die 4 is mounted. The barricade 3 is disposed on the die-bonding region 20. The light emitting diode die 4 is disposed in the region enclosed by the barricade 3. The barricade 3 is integrated into the sheet-like package body 2 or is attached to the sheet-like package body 2. The region enclosed by the barricade 3 is circular, square or rectangular, and is slightly larger than the size of the light emitting diode die 4. Thus, the barricade 3 encloses the light emitting diode die 4. The fluorescent filler 5 is fluorescent powder or fluorescent paste, and is filled in the region enclosed by the barricade 3 so as to evenly cover the surroundings of the light emitting diode die 4.

Furthermore, the present invention provides a package method of the light emitting diode 1. During the package process, the light emitting diode die 4 is mounted on the die-bonding region 20 of the sheet-like package body 2. Next, the barricade 3 is integrated into the sheet-like package body 2 or is attached to the sheet-like package body 2, and surrounds the die 4. The light emitting diode die 4 is then electrically connected to the substrate 6 through gold wires by wire bonding process. The space enclosed by the barricade 3 is filled with the fluorescent filler 5 such as silicone and transparent epoxy.

According to another embodiment of the present invention, the aforesaid steps of the package method can be partially adjusted. For example, the transparent barricade disposition step can be performed prior to the die bonding step. That is, the transparent barricade is disposed during the manufacturing step of the sheet-like package body.

According to the light emitting diode and the package method of the present invention, the sheet-like package body is not limited by the aforesaid embodiments, and can be made of various materials. The transparent barricade can be transparent paste such as silicone and epoxy, and can be disposed on any flat plate or any concave package substrate. The efficiency of the light emitting diode is not affected by the barricade.

Compared with the prior arts, the light emitting diode and the package method of the present invention can have a uniform thickness of the fluorescent filler. Each of the light beams emitted from the light emitting diode die has a substantially identical light path through the fluorescent filler so that the excellent uniformity of light output is achieved. Furthermore, the barricade allows the light to pass through it rather than being reflected, and hence the light efficiency of the light emitting diode die is not negatively affected by shielding and consequent light loss. Furthermore, the transparent barricade is not readily visible from a distance, so the appearance of the light emitting diode is more pleasing.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A light emitting diode, comprising:
a sheet-like package body comprising a die-bonding region;
a transparent barricade disposed on the die-bonding region;
a light emitting diode die disposed in the region enclosed by the barricade; and
fluorescent filler filled in the region enclosed by the barricade and covering the surroundings of the light emitting diode die.

2. The light emitting diode as in claim 1, wherein the barricade is integrated into the sheet-like package body or is attached to the sheet-like package body.

3. The light emitting diode as in claim 1, wherein the region enclosed by the barricade is circular, square or rectangular.

4. The light emitting diode as in claim 1, wherein the materials of the barricade and an encapsulation body outside the light emitting diode are silicone or transparent epoxy with approximately the same refraction coefficient.

5. The light emitting diode as in claim 1, wherein the fluorescent filler is fluorescent powder or fluorescent paste.

6. The light emitting diode as in claim 1, wherein the sheet-like package body is flat or concave.

7. A package method of a light emitting diode, comprising the steps of:
mounting a light emitting diode die on a sheet-like package body;
disposing a transparent barricade on the sheet-like package body to enclose the light emitting diode die; and
filling the region enclosed by the barricade with fluorescent filler.

8. The package method of a light emitting diode as in claim 7, wherein the step of disposing the transparent barricade is performed prior to the step of mounting a light emitting diode die.

9. The package method of a light emitting diode as in claim 8, wherein the step of disposing the transparent barricade is performed during the manufacture of the sheet-like package body.

10. The package method of a light emitting diode as in claim 9, wherein the region enclosed by the barricade is circular, square or rectangular.

11. The package method of a light emitting diode as in claim 9, wherein the materials of the barricade and an encapsulation body outside the light emitting diode are silicone or transparent epoxy with approximately the same refraction coefficient.

12. The package method of a light emitting diode as in claim 9, wherein the fluorescent filler is fluorescent powder or fluorescent paste.

13. The package method of a light emitting diode as in claim 9, wherein the sheet-like package body is flat or concave.

14. The package method of a light emitting diode as in claim 7, wherein the barricade is integrated into the sheet-like package body or is attached to the sheet-like package body.

15. The package method of a light emitting diode as in claim 14, wherein the region enclosed by the barricade is circular, square or rectangular.

16. The package method of a light emitting diode as in claim 15, wherein the materials of the barricade and an encapsulation body outside the light emitting diode are silicone or transparent epoxy with approximately the same refraction coefficient.

17. The package method of a light emitting diode as in claim 15, wherein the fluorescent filler is fluorescent powder or fluorescent paste.

18. The package method of a light emitting diode as in claim 15, wherein the sheet-like package body is flat or concave.
